(19) United States
(12) Patent Application Publication
(10) Pub. No.: US 2003/0205799 A1
(43) Pub. Date: Nov. 6, 2003

(54) Method and device for assembly of ball grid array packages

(76) Inventor: Mohammad Yunus, Dallas, TX (US)

Correspondence Address: TEXAS INSTRUMENTS INCORPORATED, P O BOX 655474, M/S 3999, DALLAS, TX, 75265

(21) Appl. No.: 10/138,392

(22) Filed: May 3, 2002

(51) Int. Cl. H01L 23/06

(52) U.S. Cl. 257/684

(57) ABSTRACT

A method for assembling FCBGA packages having fewer heating cycles and process steps than prior art is made possible through the use of a novel carrier pallet. The pallet includes recesses which mirror external solder ball contacts of the BGA package under assembly. A solder ball is positioned in each recess, a chip carrier substrate aligned and positioned atop the solder, a chip having flip chip contacts aligned to the opposite surface of the chip carrier, and the assemblage subjected to heating and cooling as required to connect both sets of contacts in a single thermal cycle. As required by the device under assembly, an underfill material and a protective cover may be included in the assembly process while making use of the carrier pallet, and without moving the devices. The carrier pallet may be used for transporting and attaching solder contacts of many types of BGA or CSP devices. Yield, reliability, and cost advantages are made possible by the invention.

### FIELD OF THE INVENTION

This invention relates generally to semiconductor devices, and more specifically to the assembly of semiconductor packages.

### BACKGROUND OF THE INVENTION

Increased circuit density, as well as high speed performance requirements have demanded changes from leaded packages with wire bonded chip interconnections, to area array solder ball contact packages (Ball Grid Array/(BGA's), and/or to flip chip integrated circuits having spherical interconnections. BGA's are in widespread use, and as a result a number of standards have been developed for the package outlines, and the input/output (I/O) array configurations. In some devices, the two interconnection techniques have been combined to form a device called a flip chip ball grid array (FCBGA). FIG. 1 illustrates this assemblage wherein a silicon chip 100 having a plurality of flip chip bumps 101 is electrically and mechanically connected to contact pads on the first surface 1051 of a substrate or chip carrier 105. The second surface 1052 of the chip carrier 105 includes a plurality of solder balls 106 for proving connection with a printed wiring board (PWB) or other next level of interconnection. An underfill material 103 fills the space between chip and substrate, and a molded cap 104 may be provided for mechanical protection of the device.

A device having FCBGA interconnections potentially has the shortest possible leads, and therefore, can support very low inductance conductors. Further, a substrate having multiple metal levels, and/or power and ground planes may provide a significant reduction in I/O count between that of the chip and the external connections of the package. Both these features are very desirable for high pin count and high performance integrated circuits.

In the flip chip process, a two dimensional array of solder wettable terminals are provided on the active surface of an integrated circuit chip, and solder wettable terminals mirroring those on the chip are provided on the first surface 1051 of the mounting substrate. Flip chip bumps are smaller in diameter, and at a tighter pitch than external BGA contact bumps. Typically, the chip contacts comprise solder, and terminals of interconnections on the chip and substrate are joined by aligning the terminals, and heating to a sufficiently high temperature to cause the solder to soften and reflow.

A polymeric underfill between the flip chip contacts, and between chip and substrate surfaces has been shown to reduce stress on the solder joints which result from thermal mismatch, and/or fatigue by cycling and activating the circuits. Typically, the underfill is thermosetting polymer applied as a paste, and after filling the voids is subsequently solidified by thermal processing to cure the polymer.

Similarly, in the BGA process, a two dimensional array of solder wettable terminals is provided on the second surface 1052 of the substrate which in turn, will mate to a predefined pattern of terminals on a circuit board, or other next level of interconnection. A sphere of solder is positioned on each terminal of the BGA, and is reflowed by thermal processing.

To complete fabrication of the device, a lid or other protective cover surrounds the back of the chip, and extends to near the perimeter of the substrate. Frequently, the protective cap is a molded polymer which provides both mechanical protection, and a thermal dissipation path.

In the fabrication of FCBGA devices, an important step is the forming and attachment of interconnections. In flip chip devices, solder bumps are typically formed by evaporation and patterning, or by plating a layer of solder onto the I/O pad of the chip so that upon heating, surface tension of the molten solder forms a spherical mass. Alternatively, solder paste is forced through a stencil by a squeegee, and the resulting decal having a plurality of solder regions are then transferred to receiving pads. Preformed spheres of solder or other conductive material having a solder coating may be attached for either flip chip or BGA contacts.

Larger solder balls for external contacts of BGA packages have been formed by aspiration of molten solder jets. More frequently, preformed solder balls are aligned through a stencil or mask so that one ball touches each fluxed pad, or the solder balls held by a vacuum chuck are aligned and brought into contact with the substrate receiving pad. Each of these processes has some limitations which increase the cost of the device, either by capital expenditure, by rework requirements, by reliability concerns, and/or by labor and time intensity.

Usually, the fabrication processes are made in sequence; a chip having flip chip solder contacts is aligned to contacts on a chip carrier substrate and heated to reflow the connections, an underfill is dispensed and heated to cure the polymer, a protective cover is attached, or the assemblage is overmolded. Finally, solder balls are positioned on the exposed surface of the substrate, and are heated to join the solder to the package. Solder ball attach processes are cumbersome, and are susceptible to omitted or misplaced contacts, resulting in either loss of the device at this final fabrication stage, or requirement for rework.

During FCBGA assembly, the device is subjected to a number of thermal cycles, each of which not only adds some level of stress on the device, but also adds to cycle time, and requires a specific piece of capital equipment. Because of these limitations, and costs, improved methods of assembly would be very beneficial to this emerging device type.

### SUMMARY OF THE INVENTION

It is an object of the invention to provide a method for assembling a flip chip ball grid array (FCBGA) device which reduces the number of process steps, and heat cycles from that of current art.

It is further an object of the invention to provide a manufacturing method which eliminates the need for some of the capital equipment used for BGA ball attachment, and a furnace used for reflowing those contacts.

The resulting manufacturing process is adaptable to any level of production from strictly manual to one which is highly automated for high volume production.

It is an object of the invention to provide an assembly method which eliminates at least one thermal process, and thereby improve reliability of the device, because of stress reduction.

It is also an object of the invention to improve yield by eliminating a process step, and the associated handling defects.

It is further an object of the invention to provide a carrier pallet having a plurality of recesses for aligning BGA solder balls to chip carrier substrates, and transporting the device during assembly.

It is an object of the invention to provide a less complex method for inspecting the location and size of solder balls prior to attachment to BGA packages.

It is an object of the invention to provide an assembly method for FCBGA, BGA, CSP or FCCSP packages.

These and other objectives are met by filling the recesses of a carrier pallet with solder balls, inspecting the balls, positioning a chip carrier substrate in contact with the solder, aligning a flip chip device onto the opposite surface of the substrate and passing the pallet through a heating cycle which allows reflowing both the solder of the BGA contacts, and the chip to substrate contacts in a single step. Underfill and capping are accomplished following the soldering process.

A reliable method of attaching a single solder ball to each BGA contact is provided by use of the novel pallet fixture. The simplified process allows both yield and reliability of the device to be enhanced by minimizing the number of steps and heat cycles.

The novel carrier pallet is compatible with standard BGA package outlines and ball arrays, or may be customized. Pallets are designed so that any number of packages may be processed simultaneously. The pallet is fabricated or coated with material which is not wetted by solder, is thermally stable at solder reflow temperatures, has thermal expansion properties similar to those of the chic carrier substrate, and has slightly larger recesses than the solder ball diameter, in order to allow ready release. The pallet of the current invention may be used for solder ball assembly of FCBGA, as well as any BGA package, chip scale package (CSP) or FCCSP (flip chip chip scale package) assembly.

Further objectives and advantages of the invention will become apparent from consideration of the drawings together with the ensuing description.

### BRIEF DESCRIPTION OF THE DRAWINGS

FIG. 1 is a cross section of a FCBGA package of prior art.

FIGS. 2a through 2d provide the typical prior process flow for a FCBGA.

FIG. 2a illustrates flip chip align and reflow connection to a substrate. (Prior art)

FIG. 2b shows underfill material dispensed and cured. (Prior art)

FIG. 2c includes a protective cap on a FCBGA. (Prior art)

FIG. 2d shows a prior package inverted with BGA ball contacts attached.

FIGS. 3a through 3e demonstrate the process flow for a FCBGA of the current invention.

FIG. 3a provides a pallet having recesses for solder balls.

FIG. 3b shows a BGA substrate positioned on the solder balls.

FIG. 3c shows a flip chip device aligned to the substrate, and both sets of solder contacts reflowed.

FIG. 3d includes an underfill polymer.

FIG. 3e illustrates a capped device which has been heated to cure both the underfill and capping polymer.

FIG. 4 is a cross section of a pallet having multiple FCBGA devices.

FIG. 5 is a pallet supporting a CSP device.

### DETAILED DESCRIPTION OF THE DRAWINGS

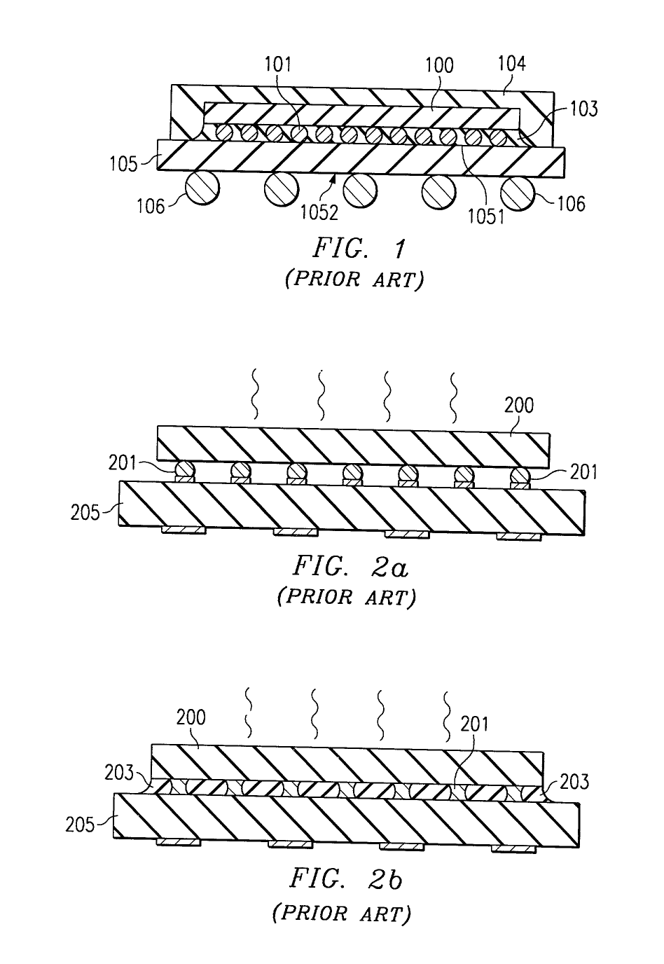

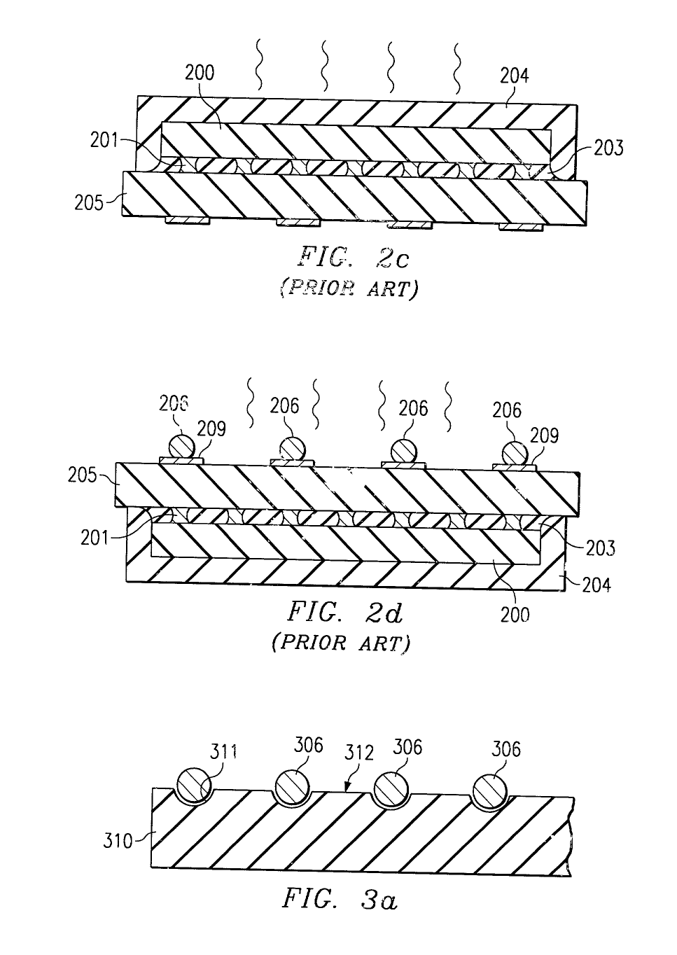

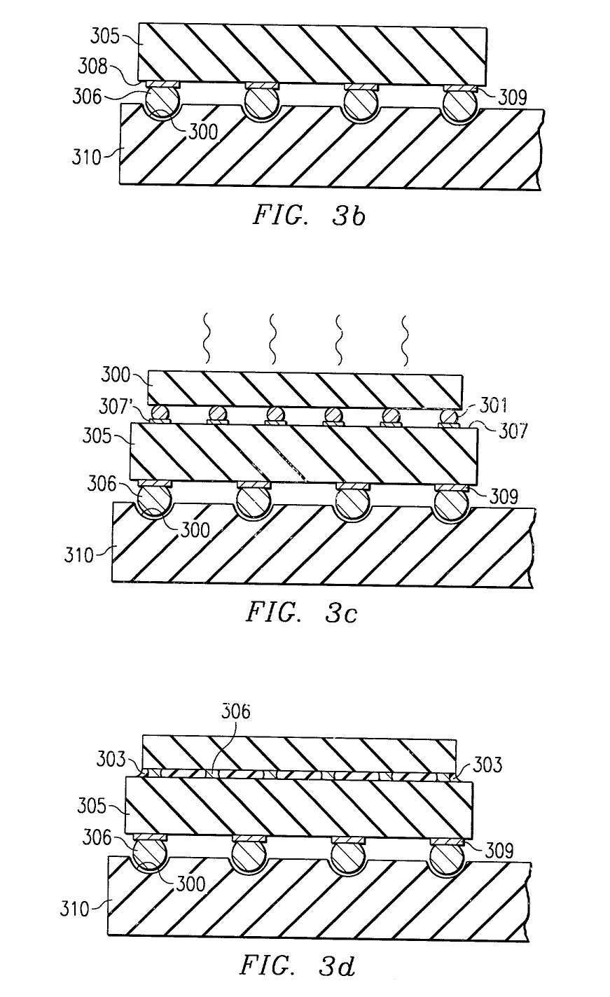

To better understand the advantages of the current invention for FCBGA fabrication, the process flow is compared in FIGS. 3a through 3e to that of known art in FIGS. 2a through 2d.

In FIG. 2a, a chip 200 having a plurality of input/output (I/O) bump contacts 201 at each I/O is aligned to and placed on corresponding contact pads of a BGA substrate 205. Typically the bump contacts comprise solder. The chip with substrate is passed through a heating apparatus at a sufficiently high temperature to cause the solder to reflow, and subsequently cooled to solidify the contacts. In FIG. 2b, an underfill polymer 203 is dispensed to fill the voids between chip contacts 201, and between the facing chip 200 and substrate 205 surfaces. The underfill 203 typically is a thermoset polymer which requires a heating cycle to solidify and cause the polymer to cure. In FIG. 2c, a protective cover 204 which extends to near the substrate 205 edge is placed over the chip. Most often, the cover 204 may be either a molded polymer, or a preformed cap which is secured by means of heat staking or filling with a polymeric material, cured by heat treatment. In FIG. 2d, the capped chip carrier is then inverted, a plurality of solder balls 206 placed on exposed contacts 209 on the BGA substrate 205, and the assemblage is passed through a reflow furnace of other heating device for reflowing and attaching the solder balls.

In this typical process flow, four separate thermal cycles are required to complete the assembly. Because the substrate most frequently is a composite or laminate polymer having a coefficient of thermal expansion significantly different from that of the silicon chip, thermal stresses are imparted on the assemblage during each cycle, with the most detrimental being those on the solder joints of the flip chip contacts.

FIGS. 3a through 3e illustrate the improved process flow of the current invention for assembly of a FCBGA.

In FIG. 3a, the cross section of a carrier pallet 310 for holding and transporting one or more BGA packages through the assembly process is illustrated. The improved flow is made possible by a novel carrier pallet. The pallet 310 includes a plurality of recesses 311 in the first surface 312 which correspond to an array of solder ball contacts on a BGA package, preferably in a standardized format. A solder ball 306 is positioned in each recess of the pallet 310 by any of a number of methods, including for example, by flooding the surface with solder spheres and blowing off the excess, by picking and placing using a vacuum apparatus, by dropping the balls through a template, or by other methods.

Ball placement is readily inspected by optical means to insure that each recess is filled with a single solder ball, and that each solder ball extends above the surface of the carrier so that contact may be made to a chip carrier substrate.

In FIG. 3b, a chip carrier substrate 305 is aligned and positioned atop the solder balls 306 so that contact terminals or pads 309 on the second surface 308 of the chip carrier are in intimate contact with the solder 306.

In FIG. 3c, an integrated circuit chip 300 having flip chip contacts 301 is aligned and positioned on contact pads 3071 located on the first surface 307 of the chip carrier. The pallet 310 with chip 300, chip carrier 305, and solder contacts 306 and 301 is passed through a heating apparatus having a thermal profile so that both the flip chip contacts to the substrate, and the BGA solder balls to the opposite surface of the substrate are attached in a single thermal process.

In FIG. 3d, an underfill 303 is dispensed and cured, and in FIG. 3e, the assembled device is covered by molding or by a preformed cap 304. Heating cycles for steps illustrated in FIGS. 3d and 3e may be combined if the materials of choice are compatible.

It can be seen that the simplified process flow of the current invention has many advantages, including an assembly system whereby the number of heating process steps is reduced from four (4) distinct cycles of the prior art to the current process having a maximum of three (3) cycles. Further, handling of the device is minimized not only by fewer process steps, but also by allowing complete assembly of the critical components on a single carrier. Further, capital equipment needs are reduced by the simpler process.

A critical component of the semiconductor assembly system of the current invention is a carrier pallet having a plurality of recesses for BGA devices. It is not unusual for multiple BGA chip carriers to be transported in an inverted position through the ball attach process on a pallet. However, it is novel to provide a carrier having recesses for positioning solder balls, and for transporting the device through multiple process steps. In a preferred embodiment, the solder ball array conforms to BGA standards, both in array format, as well as in ball size. However, customized arrays are equally applicable.

Holding and transporting FCBGA devices through the assembly process in pallet format is amenable to large scale production whereby multiple devices 420 are carried on a single pallet 410, as shown in FIG. 4, or to lab or development activities wherein a single device is held in a pallet. Further, in cases where the production does not require the number of devices necessary to completely populate all sites on the pallet, the pallet may be partially filled for processing with no detrimental effects. The level and type automated pick and place equipment, and the design of the reflow system are important considerations in the choice of pallet configuration.

The pallet carrier of the current invention comprises any of a number of non-solder wetting materials, or shaped core having a non-solder wetting coating. Readily formed materials, such as aluminum, preferably with a thermally stable polymeric coating are an example of an acceptable pallet base material. Alternivately, molded plastics provide a non-solder wetting material suitable for use as a pallet.

Preferably the base material of said pallet is similar in coefficient of thermal expansion to that of the chip carrier substrate. Typically the chip carrier substrate is a composite or laminate polymer wherein the coefficient of thermal expansion (CTE) is in the range of 15 to 35 ppm per degree, and the pallet is within the same range. However, the invention is not limited to plastic BGA packages, but is applicable to ceramic, to flex tape or other substrate materials, and in those applications, the pallet material would be matched CTE to the device under assembly.

Thermal stability of the pallet, and any coating is equal to or greater than the reflow temperature of the solder balls under assembly. Typically, the external BGA connections are a eutectic 63Sn/37Pb solder having a reflow peak temperature of approximately 210 to 220 deg C. However, the invention is not limited to eutectic solder, but is intended to include any conductive material in use for flip chip or BGA contacts.

Solder ball sizes for BGA package are typically in the range of 0.3 to 0.75 mm in diameter, and the each recess in the pallet is slightly larger than that of the specified ball. Preferably the diameter of the recess will exceed that of the solder ball by 0.03 to 0.10 mm. The increased diameter recess assures freedom for the package to be removed from the pallet. Solder is well known for self aligning properties during reflow, and therefore, a few degrees of freedom between the substrate and pallet are acceptable.

Depth of the pallet recesses is equal to approximately one half the diameters of the selected solder balls. For example ball sizes between 0.30 and 0.75 mm for BGA packages require corresponding recess depths in the range of 0.15 to 0.38 mm. This depth assures that the ball is above the surface of the pallet, and allows surface tension of the molten solder to self-align the solder balls to package contact pads.

The pallet may be formed by any of a number of processes, such as molding, punching, embossing, or other forming technique, and will be highly dependent upon the base material selection, and acceptable manufacturing techniques for that material.

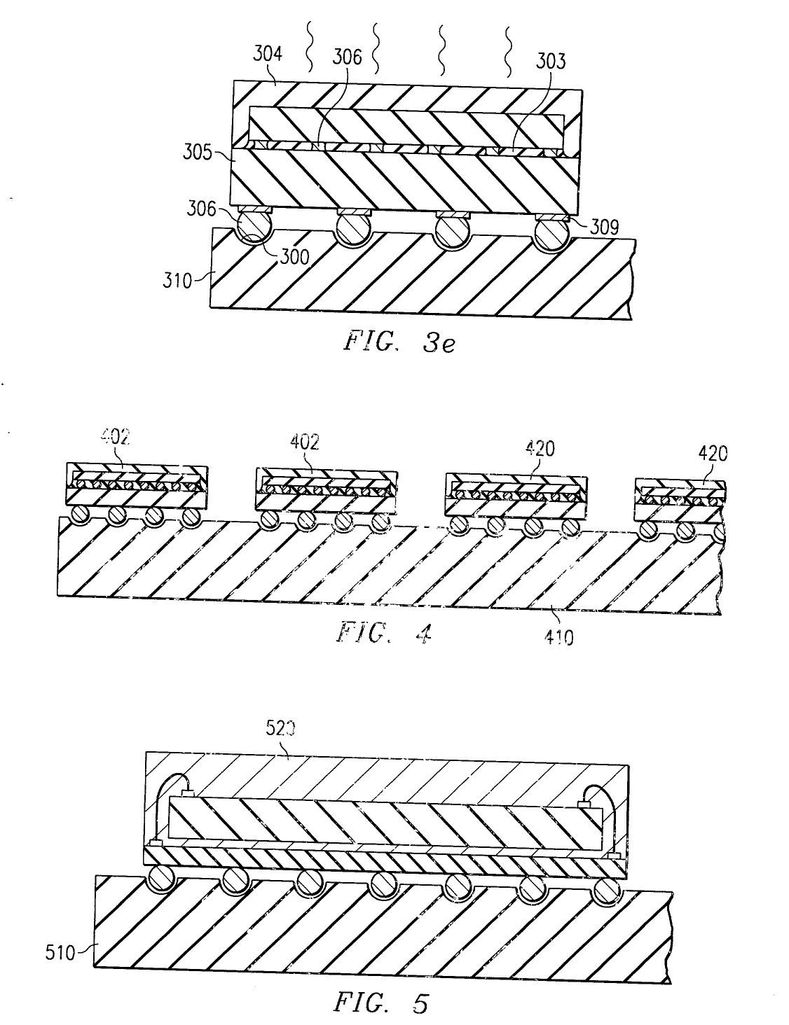

The invention has been described with reference to a simplified process for fabrication of FCBGA devices, however, it should be noted that use of a novel pallet with recesses for solder ball connections is applicable to BGA packages of different configurations and substrate types. Further, the pallet and the process are applicable to CSP devices which typically have smaller solder balls. Many types of CSP devices have been developed, and an example of a wire bonded CSP package 520 supported in a pallet 510 for contact assembly is illustrated in FIG. 5. Recessed solder ball pallet may be used for assembly of FCBGA, flip chip chip scale packages (FCCSP), or for BGA or CSP packages wherein the chip to substrate makes use of an alternate interconnection means.

Among the advantages of assembly by using the pallet for solder connection to the substrate are low cost solder ball alignment and placement, and ease of inspection. Both processes support the use of relatively inexpensive equipment.

While the present invention has been described in conjunction with particular embodiments, it should be understood that modifications and improvements will become apparent to those skilled in the art. Therefore, the invention should not be limited to the particular form set forth, but it is intended that the appended claims cover all modifications that do not depart from the soirit and scope of the invention.

What is claimed is:

1- An assembly system for semiconductor packages comprising;
a carrier pallet having one or more arrays of recesses on the first surface mirroring external contacts of a BGA package,
a solder ball positioned in each recess, and extending above said first surface of the pallet,
one or more chip carrier substrates having a second major surface with contact pads positioned atop, and in intimate contact a corresponding array of solder balls, and
an apparatus capable of heating said pallet, substrates, and solder to a temperature sufficiently high to cause solder reflow.

2- An assembly system as in claim 1 which further includes one or more flip chip semiconductor devices having a plurality of protruding contacts aligned to, and in intimate contact with corresponding contact sites on the first surface of said chip carrier substrates.

3- An assembly system as in claim 1 wherein said recesses are in the range of 0.03 to 0.1 mm larger in diameter than said solder balls for BGA packages.

4- An assembly system as in claim 1 wherein the depth of said recesses are equal to approximately one-half the diameter of said solder balls.

5- An assembly system as in claim 1 wherein said pallet is comprised of a material having a coefficient of thermal expansion similar to that of said chip carrier substrate.

6- An assembly system as in claim 1 wherein said pallet is comprised of, or coated with a non-solderable material.

7- An assembly system as in claim 1 whereby said solder balls comprise eutectic solder.

8- A carrier pallet for transport and assembly of semiconductor package having a plurality of recesses mirroring array locations of solder ball contacts on a BGA package, wherein the diameter of said recesses is slightly larger than said solder balls, and the depth of said recesses is one-half the diameter of said solder balls.

9- A carrier pallet as in claim 8 having one of more arrays of recesses, wherein the coefficient of thermal expansion is similar to that of the device under assembly.

10- A carrier pallet as in claim 8 comprising a non-solder wetting surface.

11- A carrier pallet as in claim 8 wherein said recesses mirror the external contacts of a CSP device.

12- A method for assembly of a FCBGA package including the following steps in sequence:
providing a carrier pallet having a plurality of recesses which mirror external contacts of the device under assembly,
positioning a solder ball in each active contact site,
aligning and positioning a chip carrier substrate to said solder balls,
aligning a chip having flip chip contacts to pads on the opposite surface of said chip carrier,
subjecting the carrier pallet, chip carrier substrate, and chip to a thermal process whereby all solder contacts are connected.

13- A method as in claim 12 which further includes inspection of said solder balls for location and size prior to positioning the chip carrier.

14- A method as in claim 12 which further includes dispensing and curing an underfill material between the chip and substrate.

15- A method as in claim 12 which further includes capping said interconnected device with a protective cover.
